(19) United States
(12) Patent Application Publication
(10) Pub. No.: US 2025/0362254 A1
(43) Pub. Date: Nov. 27, 2025

(54) SYSTEMS AND METHODS OF DEFECT DETECTION BY VOLTAGE CONTRAST IMAGING

(71) Applicant: ASML Netherlands B.V., Veldhoven (NL)

(72) Inventors: Wei-Hsin HSIEH, Hsinchu (TW); Datong ZHANG, San Jose, CA (US); Xuechen ZHU, San Jose, CA (US); Yew Kong TANG, Singapore (SG); Chun-Wei HUANG, Hsinchu (TW); Lichi WANG, Meridian, ID (US)

(73) Assignee: ASML Netherlands B.V., Veldhoven (NL)

(21) Appl. No.: 18/871,782

(22) PCT Filed: May 15, 2023
(86) PCT No.: PCT/EP2023/062940

§ 371 Date: Dec. 4, 2024

Related U.S. Application Data
(60) Provisional application No. 63/352,924, filed on Jun. 16, 2022.

(51) Int. Cl. G01N 23/2251; G01R 31/307; G03F 7/00

(52) U.S. Cl. CPC G01N 23/2251; G01R 31/307; G03F 7/7065; G03F 7/70655; G01N 2223/418; G01N 2223/6116; G01N 2223/6462

(57) ABSTRACT

Systems and methods of detecting a defect in a sample using a charged-particle beam apparatus are disclosed. The apparatus may include a charged-particle source configured to emit charged particles and a controller including circuitry configured to irradiate a region of a sample comprising a plurality of features with a first dosage of charged particles of the primary charged-particle beam; inspect the plurality of features using a second dosage of the charged particles of the primary charged-particle beam, acquire an image of the inspected plurality of features; and determining whether there is a defect based on a gray level value of a feature of the plurality of features, wherein the first dosage is smaller than a saturation dosage, and wherein the saturation dosage comprises a total number of charged particles exceeding a charge storage capacity of the feature.

### CROSS-REFERENCE TO RELATED APPLICATIONS

This application claims priority of U.S. application 63/352,924 which was filed on 16 Jun. 2022 and which is incorporated herein in its entirety by reference.

### TECHNICAL FIELD

The embodiments provided herein disclose a charged-particle beam apparatus, and more particularly systems and methods for improving voltage contrast defect detection capabilities in three-dimensional (3D) structures.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the complexity in device architecture increases, accurate inspection of 3D structures has become more important. Although voltage contrast inspection techniques may be employed to detect buried physical or electrical defects in such complex device structures, the existing techniques suffer from low inspection throughput, stringent stage positioning and high movement accuracy requirements, limitations in the size of regions of interest, among other things.

### SUMMARY

One aspect of the present disclosure is directed to a charged-particle beam apparatus to detect a defect in a sample. The charged-particle beam apparatus may include a charged-particle source configured to emit charged particles, the emitted charged particles forming a primary charged-particle beam. The apparatus may further include a controller including circuitry configured to irradiate a region of a sample comprising a plurality of features with a first dosage of charged particles of the primary charged-particle beam, inspect the plurality of features using a second dosage of the charged particles of the primary charged-particle beam, the second dosage being different from the first dosage, acquire an image of the inspected plurality of features, and determining whether there is a defect based on a gray level value of a feature of the plurality of features, the gray level value determined from the acquired image of the plurality of features, wherein the first dosage is smaller than a saturation dosage, and wherein the saturation dosage comprises a total number of charged particles exceeding a charge storage capacity of the feature.

Another aspect of the present disclosure is directed to a charged-particle beam apparatus to detect a defect in a sample. The charged-particle beam apparatus may include a charged-particle source configured to emit charged particles, the emitted charged particles forming a primary charged-particle beam. The apparatus may further include a controller including circuitry configured to irradiate a region of a sample comprising a plurality of contact pads with a first dosage of charged particles of the primary charged-particle beam, the plurality of contact pads configured to form an electrical connection to a corresponding plurality of word-lines of a memory device, inspect the plurality of contact pads using a second dosage of the charged particles of the primary charged-particle beam, the second dosage being different from the first dosage, acquire an image of the inspected plurality of contact pads, and determine whether there is a defect based on a gray level value of a contact pad of the plurality of contact pads, the gray level value determined from the acquired image of the plurality of contact pads, wherein the first dosage is smaller than a saturation dosage, and wherein the saturation dosage comprises a total number of charged particles exceeding a charge storage capacity of a word-line of the plurality of word-lines.

Another aspect of the present disclosure is directed to a method of detecting a defect in a sample using a charged-particle beam apparatus. The method may include irradiating a region of a sample comprising a plurality of features using a charged-particle beam to charge each of the plurality of features with a first dosage of charged particles of the charged-particle beam, inspecting the plurality of features using a second dosage of charged particles of the charged-particle beam, the second dosage being different from the first dosage, acquiring an image of the inspected plurality of features, and determining whether there is a defect based on a gray level value of a feature, the gray level value determined from the acquired image of the plurality of features, wherein the first dosage is smaller than a saturation dosage, and wherein the saturation dosage comprises a total number of charged particles exceeding a charge storage capacity of the feature.

Another aspect of the present disclosure is directed to a method of detecting a defect in a sample using a charged-particle beam apparatus. The method may include irradiating a region of a sample comprising a plurality of features using a charged-particle beam to charge each of the plurality of features with a first dosage of charged particles of the charged-particle beam, inspecting the plurality of features using a second dosage of charged particles of the charged-particle beam, the second dosage being different from the first dosage, acquiring an image of the inspected plurality of features, and determining whether there is a defect based on a gray level value of a feature, the gray level value determined from the acquired image of the plurality of features, wherein the first dosage is smaller than a saturation dosage, and wherein the saturation dosage comprises a total number of charged particles exceeding a charge storage capacity of the feature.

Another aspect of the present disclosure is directed to a method of detecting a defect in a sample using a charged-particle beam apparatus. The method may include irradiating a region of a sample comprising a plurality of contact pads using a charged-particle beam to charge each of the plurality of contact pads with a first dosage of charged particles of the charged-particle beam, the plurality of contact pads configured to form an electrical connection to a corresponding plurality of word-lines of a memory device, inspecting the plurality of contact pads using a second dosage of charged particles of the charged-particle beam, the second dosage being different from the first dosage, acquiring an image of the plurality of contact pads, and determining whether there is a defect based on a gray level value of a contact pad of the plurality of contact pads, the gray level value determined from the acquired image of the plurality of contact pads, wherein the first dosage is smaller than a saturation dosage, and wherein the saturation dosage comprises a total number of charged particles exceeding a charge storage capacity of a word-line of the plurality of word-lines.

Another aspect of the present disclosure is directed to a non-transitory computer readable medium storing a set of instructions that is executable by one or more processors of a charged-particle beam apparatus to cause the charged-particle beam apparatus to perform a method for detecting a defect in a sample using the charged-particle beam apparatus. The method may include irradiating a region of a sample comprising a plurality of features using a charged-particle beam to charge each of the plurality of features with a first dosage of charged particles of the charged-particle beam, inspecting the plurality of features using a second dosage of charged particles of the charged-particle beam, the second dosage being different from the first dosage, acquiring an image of the inspected plurality of features, and determining whether there is a defect based on a gray level value of a feature, the gray level value determined from the acquired image of the plurality of features, wherein the first dosage is smaller than a saturation dosage, and wherein the saturation dosage comprises a total number of charged particles exceeding a charge storage capacity of the feature.

Another aspect of the present disclosure is directed to a non-transitory computer readable medium storing a set of instructions that is executable by one or more processors of a charged-particle beam apparatus to cause the charged-particle beam apparatus to perform a method for detecting a defect in a sample using the charged-particle beam apparatus. The method may include irradiating a region of a sample comprising a plurality of contact pads using a charged-particle beam to charge each of the plurality of contact pads with a first dosage of charged particles of the charged-particle beam, the plurality of contact pads configured to form an electrical connection to a corresponding plurality of word-lines of a memory device, inspecting the plurality of contact pads using a second dosage of charged particles of the charged-particle beam, the second dosage being different from the first dosage, acquiring an image of the plurality of contact pads, and determining whether there is a defect based on a gray level value of a contact pad of the plurality of contact pads, the gray level value determined from the acquired image of the plurality of contact pads, wherein the first dosage is smaller than a saturation dosage, and wherein the saturation dosage comprises a total number of charged particles exceeding a charge storage capacity of a word-line of the plurality of word-lines.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 is a schematic diagram illustrating an exemplary electron beam inspection (EBI) system, consistent with embodiments of the present disclosure.

FIG. 2 is a schematic diagram illustrating an exemplary electron beam tool that can be a part of the exemplary electron beam inspection system of FIG. 1, consistent with embodiments of the present disclosure.

FIG. 3 is a schematic diagram illustrating a staircase structure of an exemplary 3D NAND memory device.

FIG. 4 illustrates a schematic representation of a gray level value signal of a contact to a non-defective word-line upon application of a dosage of charged particles, consistent with embodiments of the present disclosure.

FIG. 5 illustrates a schematic representation of a gray level value signal in response to applying a dosage of charged particles from the charged particle beam in a pre-scan mode, consistent with embodiments of the present disclosure.

FIG. 6 illustrates a schematic diagram of word-lines and corresponding contacts exposed to a pre-scan followed by a detection scan in a region of interest (ROI), consistent with embodiments of the present disclosure.

FIG. 7 illustrates a perspective view of an exemplary stack of word-lines, consistent with embodiments of the disclosure.

FIG. 8A illustrates a cross-section view of an exemplary word-line stack including a defect, consistent with embodiments of the disclosure.

FIG. 8B illustrates an exploded view of an exemplary word-line, consistent with embodiments of the present disclosure.

FIG. 9 is a data plot of simulated capacitance values of a capacitor with varying thicknesses, consistent with embodiments of the present disclosure.

FIG. 10 is a process flowchart for an exemplary method of detecting a defect, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC, thereby rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

In semiconductor devices, buried defects such as voids or particles may cause full opens and leakages (shorts), or in some cases, a partial open or a partial leakage. Existing voltage contrast inspection techniques, used to detect such defects, involve flood exposure of negatively charged particles e.g., electrons, on a surface and rely on differences in surface potential measurements of structures on the surface. The gray level of a pixel representing a surface region with high surface potential is higher (appears brighter in a SEM image) than the gray level of the pixel representing a lower surface potential region. The gray levels of structures are compared to a reference gray level to detect a defect. The existing technique for detecting defects using voltage contrast inspection is based on a selective pre-scan approach, in which a small portion of the features of interest are charged using a saturation dosage of charged particles. Some of the several drawbacks associated with this approach include low inspection throughput, high stage positioning and movement accuracy requirement, limitations to the scannable size of region of interest, instability in charging control, among other things.

Some embodiments of the present disclosure are directed to apparatuses and methods for detecting a defect in a sample by voltage contrast inspection. The method may include a pre-scan step and an inspection step. In the pre-scan step, one or more features such as a contact pad to a word-line of a 3D NAND device, may be irradiated using a low dosage of charged particles. The dosage of charged particles used in the pre-scan step may be lower than a threshold dosage. In the inspection step, following the pre-scan step, the features may be inspected using a second dosage of charged particles which, upon interaction with the features may generate signal charged particles, such as secondary or backscattered electrons in a SEM. A defect in the feature may be detected based on a gray level value of the feature in the acquired image. A non-defective feature, exposed to the low-dosage pre-scan, may appear as a dark pixel or exhibit a dark voltage contrast signal whereas defective features associated with a defect may appear as bright pixels or exhibit a bright voltage contrast signal exposed to the low-dosage pre-scan. Using a low-dosed pre-scan flooding of charged particles to detect a defect in complex device architecture such as that of a 3D NAND device, may enable inspection of larger regions of interest with less stringent stage positioning and movement accuracy requirements, while maintaining high inspection throughput.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

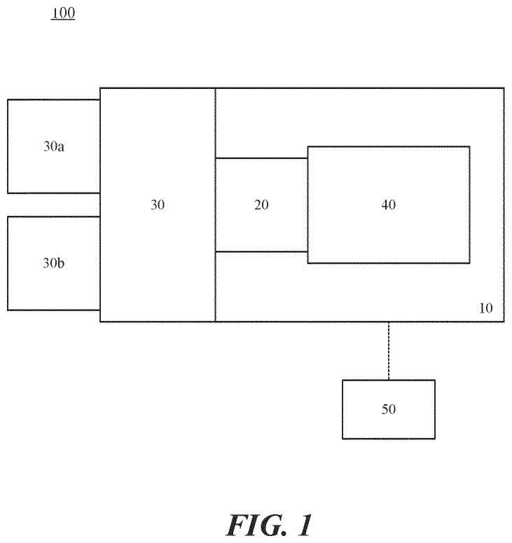

Reference is now made to FIG. 1, which illustrates an exemplary electron beam inspection (EBI) system 100 consistent with embodiments of the present disclosure. As shown in FIG. 1, charged particle beam inspection system 100 includes a main chamber 10, a load-lock chamber 20, an electron beam tool 40, and an equipment front end module (EFEM) 30. Electron beam tool 40 is located within main chamber 10. While the description and drawings are directed to an electron beam, it is appreciated that the embodiments are not used to limit the present disclosure to specific charged particles.

EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 30 transport the wafers to load-lock chamber 20.

Load-lock chamber 20 is connected to a load/lock vacuum pump system (not shown), which removes gas molecules in load-lock chamber 20 to reach a first pressure below the atmospheric pressure. After reaching the first pressure, one or more robot arms (not shown) transport the wafer from load-lock chamber 20 to main chamber 10. Main chamber 10 is connected to a main chamber vacuum pump system (not shown), which removes gas molecules in main chamber 10 to reach a second pressure below the first pressure. After reaching the second pressure, the wafer is subject to inspection by electron beam tool 40. In some embodiments, electron beam tool 40 may comprise a single-beam inspection tool. In other embodiments, electron beam tool 40 may comprise a multi-beam inspection tool.

Controller 50 may be electronically connected to electron beam tool 40 and may be electronically connected to other components as well. Controller 50 may be a computer configured to execute various controls of charged particle beam inspection system 100. Controller 50 may also include processing circuitry configured to execute various signal and image processing functions. While controller 50 is shown in FIG. 1 as being outside of the structure that includes main chamber 10, load-lock chamber 20, and EFEM 30, it is appreciated that controller 50 can be part of the structure.

While the present disclosure provides examples of main chamber 10 housing an electron beam inspection system, it should be noted that aspects of the disclosure in their broadest sense, are not limited to a chamber housing an electron beam inspection system. Rather, it is appreciated that the foregoing principles may be applied to other chambers as well.

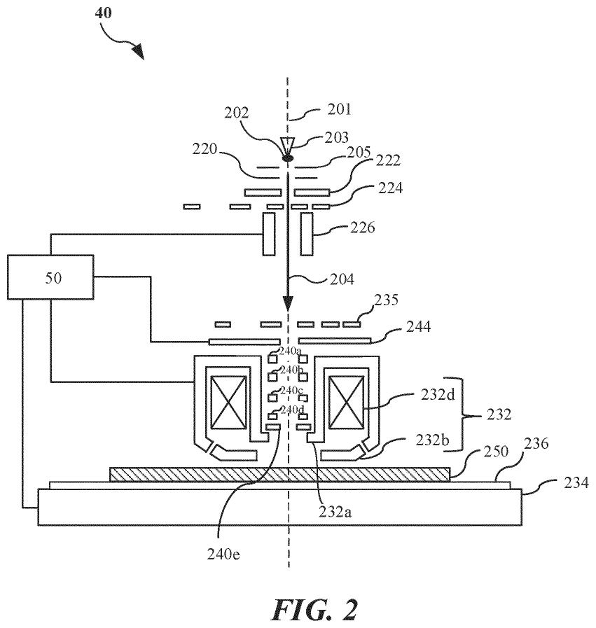

Reference is now made to FIG. 2, which illustrates a schematic diagram illustrating an exemplary configuration of electron beam tool 40 that can be a part of the exemplary charged particle beam inspection system 100 of FIG. 1, consistent with embodiments of the present disclosure. Electron beam tool 40 (also referred to herein as apparatus 40) may comprise an electron emitter, which may comprise a cathode 203, an extractor electrode 205, a gun aperture 220, and an anode 222. Electron beam tool 40 may further include a Coulomb aperture array 224, a condenser lens 226, a beam-limiting aperture array 235, an objective lens assembly 232, and an electron detector 244. Electron beam tool 40 may further include a sample holder 236 supported by motorized stage 234 to hold a sample 250 to be inspected. It is to be appreciated that other relevant components may be added or omitted, as needed.

In some embodiments, electron emitter may include cathode 203, an anode 222, wherein primary electrons can be emitted from the cathode and extracted or accelerated to form a primary electron beam 204 that forms a primary beam crossover 202. Primary electron beam 204 can be visualized as being emitted from primary beam crossover 202.

In some embodiments, the electron emitter, condenser lens 226, objective lens assembly 232, beam-limiting aperture array 235, and electron detector 244 may be aligned with a primary optical axis 201 of apparatus 40. In some embodiments, electron detector 244 may be placed off primary optical axis 201, along a secondary optical axis (not shown).

Objective lens assembly 232, in some embodiments, may comprise a modified swing objective retarding immersion lens (SORIL), which includes a pole piece 232a, a control electrode 232b, a beam manipulator assembly comprising deflectors 240a, 240b, 240d, and 240e, and an exciting coil 232d. In a general imaging process, primary electron beam 204 emanating from the tip of cathode 203 is accelerated by an accelerating voltage applied to anode 222. A portion of primary electron beam 204 passes through gun aperture 220, and an aperture of Coulomb aperture array 224, and is focused by condenser lens 226 so as to fully or partially pass through an aperture of beam-limiting aperture array 235. The electrons passing through the aperture of beam-limiting aperture array 235 may be focused to form a probe spot on the surface of sample 250 by the modified SORIL lens and deflected to scan the surface of sample 250 by one or more deflectors of the beam manipulator assembly. Secondary electrons emanated from the sample surface may be collected by electron detector 244 to form an image of the scanned area of interest.

In objective lens assembly 232, exciting coil 232d and pole piece 232a may generate a magnetic field. A part of sample 250 being scanned by primary electron beam 204 can be immersed in the magnetic field and can be electrically charged, which, in turn, creates an electric field. The electric field may reduce the energy of impinging primary electron beam 204 near and on the surface of sample 250. Control electrode 232b, being electrically isolated from pole piece 232a, may control, for example, an electric field above and on sample 250 to reduce aberrations of objective lens assembly 232 and control focusing situation of signal electron beams for high detection efficiency, or avoid arcing to protect sample. One or more deflectors of beam manipulator assembly may deflect primary electron beam 204 to facilitate beam scanning on sample 250. For example, in a scanning process, deflectors 240a, 240b, 240d, and 240e can be controlled to deflect primary electron beam 204, onto different locations of top surface of sample 250 at different time points, to provide data for image reconstruction for different parts of sample 250. It is noted that the order of 240a-e may be different in different embodiments.

Backscattered electrons (BSEs) and secondary electrons (SEs) can be emitted from the part of sample 250 upon receiving primary electron beam 204. A beam separator can direct the secondary or scattered electron beam(s), comprising backscattered and secondary electrons, to a sensor surface of electron detector 244. The detected secondary electron beams can form corresponding beam spots on the sensor surface of electron detector 244. Electron detector 244 can generate signals (e.g., voltages, currents) that represent the intensities of the received secondary electron beam spots, and provide the signals to a processing system, such as controller 50. The intensity of secondary or backscattered electron beams, and the resultant secondary electron beam spots, can vary according to the external or internal structure of sample 250. Moreover, as discussed above, primary electron beam 204 can be deflected onto different locations of the top surface of sample 250 to generate secondary or scattered electron beams (and the resultant beam spots) of different intensities. Therefore, by mapping the intensities of the secondary electron beam spots with the locations of sample 250, the processing system can reconstruct an image that reflects the internal or external structures of wafer sample 250.

In some embodiments, controller 50 may comprise an image processing system that includes an image acquirer (not shown) and a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detector 244 of apparatus 40 through a medium such as an electrical conductor, optical fiber cable, portable storage media, IR, Bluetooth, internet, wireless network, wireless radio, among others, or a combination thereof. In some embodiments, the image acquirer may receive a signal from electron detector 244 and may construct an image. The image acquirer may thus acquire images of regions of sample 250. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, controller 50 may include measurement circuitries (e.g., analog-to-digital converters) to obtain a distribution of the detected secondary electrons and backscattered electrons. The electron distribution data collected during a detection time window, in combination with corresponding scan path data of a primary beam 204 incident on the sample (e.g., a wafer) surface, can be used to reconstruct images of the wafer structures under inspection. The reconstructed images can be used to reveal various features of the internal or external structures of sample 250, and thereby can be used to reveal any defects that may exist in the wafer.

In some embodiments, controller 50 may control motorized stage 234 to move sample 250 during inspection. In some embodiments, controller 50 may enable motorized stage 234 to move sample 250 in a direction continuously at a constant speed. In other embodiments, controller 50 may enable motorized stage 234 to change the speed of the movement of sample 250 over time depending on the steps of scanning process.

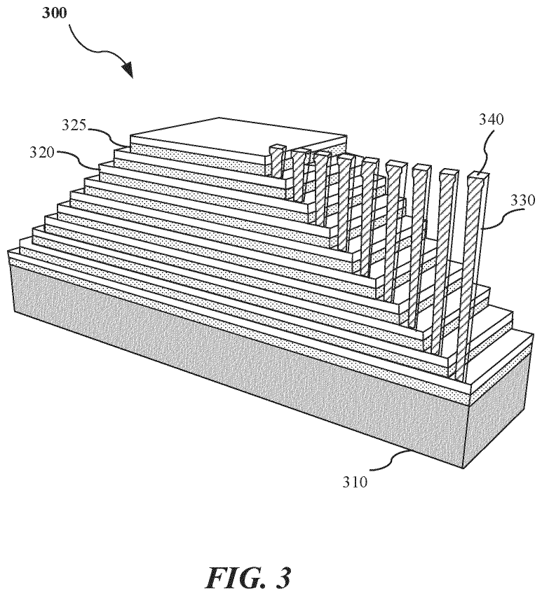

Reference is now made to FIG. 3, which illustrates a schematic diagram of an exemplary memory device 300 having a “staircase” structure. Device 300 may include multiple memory cells vertically stacked on a substrate 310. Device 300 may be fabricated, for example, by depositing multiple alternating layers of dielectric materials, such as oxides and nitride films 325. Memory device 300 may include horizontal word-lines 320, which may be formed by backfilling with a conductive material, such as tungsten, after the sacrificial layers, e.g., nitride films in the stack, have been removed. Memory cell formation in device 300 may further include a staircase etch of the dielectric film pairs and metal fill of contact channels 330 comprising a contact pad 340 for enabling a bit-line bus contact (not illustrated in FIG. 3) to the word-lines. Multiple word-line lithography steps with repeated vertical step etching and 2D trimming at each staircase may be performed to provide the “up and down” shape of the WL staircase used in 3D NAND devices. This series of process steps requires precise etch step profiling, trim etch uniformity, and pull-back CD control for the WL contact. The length of the WL staircase may increase as more memory cells are vertically stacked to improve efficiency, storage density, among other things. Device 300 may include a film stack that may be >64 layers thick, or >96 layers thick, or in some cases, even >124 layers thick. A vertical channel hole (not illustrated) may further be created with a high aspect ratio (HAR) etch, through the entire film stack. In some cases, the HAR may be >100:1. Individual memory cells within layers may be electrically connected through word-line replacement metal fills, provided by materials such as tungsten, for example. The word-line metal filling may include void-free filling of complex, narrow, lateral structures with minimal stress on the device stack. In practice, fabricating a 3D NAND device is extremely challenging and it may be desirable to detect physical or electrical defects generated during or after fabrication of such complex device structures.

Detecting buried defects in vertical high-density structures such as 3D NAND flash memory device 300, can be challenging. One of several ways to detect buried or on-surface electrical defects in such devices is by using a voltage contrast method in a SEM. In this method, electrical conductivity differences in materials, structures, or regions of a sample cause contrast differences in SEM images thereof. In the context of defect detection, an electrical defect under the sample surface may generate a charging variation on the sample surface, so the electrical defect can be detected by a contrast in the SEM image of the sample surface. To enhance the voltage contrast, a process called pre-charging or flooding may be employed in which the region of interest of the sample may be exposed to a large beam current before an inspection using a small beam current but high imaging resolution. For the inspection, some of the advantages of flooding may include reduction of charging of the wafer to minimize distortion of images due to the charging, and in some cases, increase of charging of the wafer to enhance difference of defective and surrounding non-defective features in images, among other things. Some inspection systems, such as a SEM, equipped to detect defects of a wafer using the voltage contrast method may be operated in multiple modes such as a flooding mode to highlight the defect, followed by an inspection mode to detect the defect. In the flooding mode, it may be preferable to allow maximum electrons to pass through an aperture and maximize the beam current of the primary electron beam irradiating the sample, to enhance the voltage contrast. In the inspection mode, however, a small probe spot having a small beam current may be desirable for high resolution imaging.

In semiconductor devices, buried defects such as voids or particles may cause full opens and leakages (shorts), or in some cases, a partial open or a partial leakage. Existing voltage contrast inspection techniques, used to detect such defects, involve flood exposure of negatively charged particles e.g., electrons, on a surface and rely on differences in surface potential measurements of structures on the surface. The gray level of a pixel representing a surface region with high surface potential is higher (appears brighter in a SEM image) than the gray level of the pixel representing a lower surface potential region. The gray levels of structures are compared to a reference gray level to detect a defect.

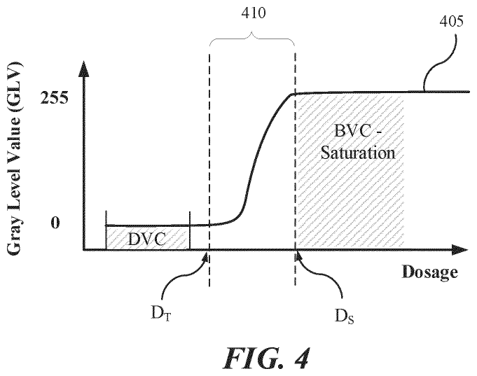

Reference is now made to FIG. 4, which illustrates a schematic representation of a gray level value signal of a contact to a non-defective word-line upon application of a dosage of charged particles, consistent with embodiments of the present disclosure. In this context, a “non-defective” feature is referred to as a feature, a structure, or a device that does not have or is not associated with a physical or an electrical defect. In some cases, a physical defect such as an under-etched metal line or an over-etched dielectric film, may result in an electrical defect. As used herein, a gray level value of a feature refers to a gray scale level of the feature as observed in an image (e.g., a SEM image). As an example, in an 8-bit grayscale image, there may be 256 discrete gray scale levels and each pixel may be assigned a gray scale value between “0” and “255,” where gray level 0 indicates a dark pixel and gray level 255 indicates a bright pixel. In the context of this disclosure, a “dosage” refers to the total number of charged particles a feature may be exposed to. In some embodiments, the charged particles may comprise electrons, for example in a SEM. In cases where the dosage comprises electrons, the dosage may be expressed as the total number of electrons, or the total charge, in Coulombs, carried by the total number of electrons. It is to be appreciated that the charge of an electron may be 1.6×10⁻¹⁹ Coulombs. A dosage of charged particles may be applied to by, for example, applying a voltage signal configured to supply a desired number of charges or charged particles to a contact.

FIG. 4 illustrates a plot 405 representing a relationship between the gray level value signal and dosage for a non-defective feature. In some embodiments, a feature may refer to a contact pad configured to form an electrical connection with a capacitor or a word-line. In some embodiments, a feature may refer to a capacitor, a metal line, a word-line, a bit-line, a gate structure, or any component of an electric circuit. In the context of FIG. 4, a feature refers to a word-line of a 3D NAND device. The word-line (e.g., word-line 320 of FIG. 3) may comprise a capacitor having a plate-like structure.

As shown in FIG. 4, a non-defective word-line, at lower dosage of charged particles, may be able to store the charged particles, behaving similar to a charge drain or a grounded capacitor. At such lower dosages, the contact pad corresponding to the non-defective word-line may appear as a dark pixel in an image. This region of low dosage and low gray level value is indicated as the dark voltage contrast (DVC region of FIG. 4) region. As the dosage increases, the capacitor gets “charged,” because it can no longer dissipate the injected charges. The dosage corresponding to the onset of charging of the capacitor, indicated as D_{T}, is referred to as the threshold dosage. Region 410 may be referred to as the transition region, where the capacitor continues to be charged. In this region, the injected charges are stored in the capacitor and the surface potential of the capacitor increases significantly. The rise in surface potential manifests as a sharp rise in the gray level value signal. The capacitor is fully charged at a dosage D_{S}, the saturation dosage. This region of high dosage and high gray level value signal is indicated as the bright voltage contrast (BVC region of FIG. 4) region. At and beyond the saturation dosage D_{S}, the incoming charges may be reflected back due to the high surface potential of the capacitor, causing the corresponding pixel to appear bright. It is to be appreciated that plot 405 is a schematic representation for illustrative purposes, and not an actual data plot, of the relationship between the gray level value signal and the dosage of charges applied to a non-defective word-line. The plot 415 is not drawn to scale.

In some embodiments, threshold dosage D_{T} may comprise a range of dosage values. For example, the threshold dosage range may be within 5% of D_{T}, or within 10% of D_{T}, or within 15% of D_{T}, or any suitable range. In some embodiments, transition region 410 may comprise a range of dosage values between threshold dosage D_{T} and saturation dosage D_{S}. In some embodiments, saturation dosage D_{S} may comprise a range of dosage values. For example, the saturation dosage range may be within % of D_{S}, or within 10% of D_{S}, or within 15% of D_{S}, or any suitable range. It is to be appreciated that the threshold dosage, the transition region, or the saturation dosage of a feature may be based on a number of factors including, but not limited to, material of fabrication, presence of defects, dimensions of the feature, among other things.

In some existing voltage contrast based techniques for inspection of 3D NAND device structures, the flooding mode or the pre-scan mode of operation may include selectively “charging” or exposing a portion of the region of interest (ROI) of a sample with an abundance of charged particles. As an example, a selected word-line contact or a few selected word-line contacts may be charged up with an over-dosed pre-scan using a charged particle beam such as a primary electron beam in a SEM. In this context, over-dosed pre-scan refers to exposing a feature with a beam having a dosage equal to or greater than the saturation dosage D_{S}. The pre-scan may be followed by a detection scan, which includes inspecting a neighboring word-line contact with a charged particle beam having a small beam current. If there is an electrical connection (e.g., a leakage) between the pre-scanned word-line contact and the neighboring word-line contact, charges injected into the pre-scanned word-line contact may travel to the neighboring word-line contact, causing the neighboring word-line contact to “charge up” and appear as a bright pixel in the image. If there is no electrical connection between the two word-line contacts, substantially no charges may flow to the neighboring word-line contact, causing the neighboring word-line contact to appear as a dark pixel (low gray level value signal). Though the selective pre-scan approach may seem effective, there are several challenges associated, some of which include a low inspection throughput, high stage accuracy requirement, limited scanned region of interest, or instability in charging control, among other issues. Therefore, it may be desirable to detect defects in 3D NAND structures while overcoming one or more challenges with the existing voltage contrast inspection techniques.

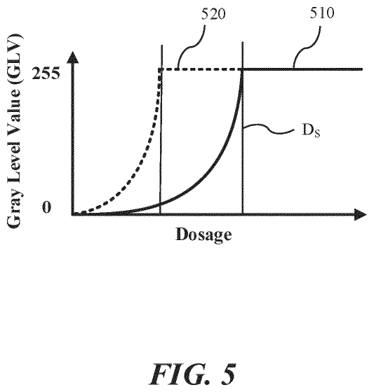

Reference is now made to FIG. 5, which illustrates a schematic representation of a gray level value signal in response to applying a dosage of charged particles from the charged particle beam in a pre-scan mode, consistent with embodiments of the present disclosure. Plot 510 represents the gray level value signal of a word-line contact to a non-defective word-line in response to application of a dosage of charged particles from the charged-particle beam. Plot 520 represents the gray level value signal of a word-line contact to a defective word-line in response to application of a dosage of charged particles from the charged-particle beam. A defect may include, but is not limited to, a word-line-word-line leakage or a word-line-word-line electrical short between two word-lines.

In the context of this disclosure, an applied dosage of charged particles from the charged-particle beam refers to the total number of charges (e.g., electrons in an electron beam) with reference to the saturation dosage D_{S}. In some embodiments, the applied dosage may be an under-dosage of charged particles if a ratio between the applied dosage of charged particles and the saturation dosage of charged particles is less than 1. In some embodiments, an under-dosage of applied charges may refer to a ratio of applied dosage to saturation dosage between 0.4 and 0.8, or between 0.45 and 0.75, or between 0.5 and 0.70, or between 0.55 and 0.65, or between 0.55 and 0.6. In some embodiments, the ratio of the total number of charges applied to the saturation dosage may be 0.55. In some embodiments, the applied dosage may be an over-dosage of charged particles if the ratio between the applied dosage of charged particles and the saturation dosage is 1 or higher.

In existing selective pre-scanning technique, an over-dosed or a saturation dosage may be applied to a few selected contacts. At saturation dosages, contacts to a defective and a non-defective word-line may both appear as bright pixels with high word-line signal, as represented by plot 510 of FIG. 5. The gray level value signal comparison may fail to provide the difference in contrast of the corresponding pixels. However, because only a few selected contacts are configured to receive the dosage of charges, defects may be detected based on the gray level value signal of a contact that is adjacent to the contact to which the signal is applied. In other words, although all the contacts to which an over-dosed pre-scan signal is applied may appear bright, the gray level value signal of a contact to which a signal is not applied may be inspected to determine the defect. As discussed above, the selective pre-scan approach suffers from several disadvantages including low throughput, smaller ROI, stringent stage accuracy requirements, or unstable charging control, among other things, rendering the inspection technique inadequate.

As illustrated in FIG. 5, the gray level value signal of the contact to a defective word-line may saturate at a much lower dosage value compared to non-defective word-line. At the dosage value corresponding to the maximum gray level value signal of plot 520, the gray level value signal of the contact to a non-defective word-line shown by plot 510 is low, indicating a dark pixel. At the same dosage value, however, the gray level value signal of the contact to a defective word-line shown by plot 520 is maximum, indicating a bright pixel. In some embodiments, the contrast in gray level values of contacts to a defective and a non-defective word-line at a dosage value smaller than the saturation dosage may be used to identify a defect in the pre-scan or the flooding mode.

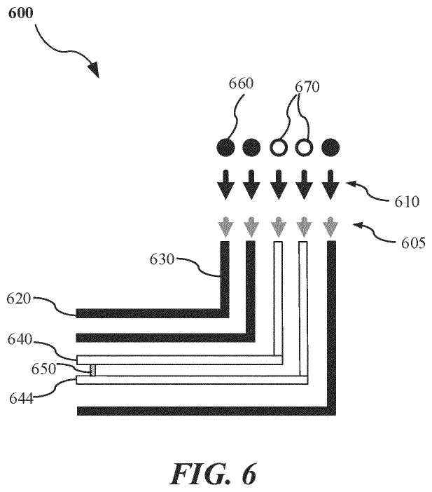

Reference is now made to FIG. 6, which illustrates a schematic diagram of word-lines and corresponding contacts exposed to a pre-scan followed by a detection scan in a region of interest (ROI) 600, consistent with embodiments of the present disclosure. Although ROI 600 is shown to include only five word-lines 620 and word-line contacts 630, it is appreciated that ROIs may include more or fewer word-lines and corresponding word-line contacts. FIG. 6 illustrates a side elevational view of a portion of a staircase structure, such as in a 3D NAND device.

ROI 600 may include word-lines 620 and high aspect ratio contacts 630 to the corresponding word-lines. In some embodiments, a pre-scan signal 605 including an under-dosage of charged particles (e.g., electrons) may be applied to each word-line contact 630. As an example, if the saturation dosage for a word-line contact is 5000 electrons (or ˜8×10¹⁶ C), the under-dosage signal may be 2750 electrons (or ˜4×10−16 C). In some embodiments, the ratio between the signal corresponding to under-dosage and the signal corresponding to saturation dosage may be less than 0.8, or less than 0.75, or less than 0.7, or less than 0.6, or less than 0.5. In some embodiments, the ratio may be 0.55. The pre-scan mode or the flooding mode in a voltage contrast technique may inject charges into the features of interest in a ROI. In some embodiments, the charged particles flooding the ROI may include, but are not limited to, electrons.

In some embodiments, a detection or an inspection signal 610 may be applied following the pre-scan signal. In some embodiments, detection signal 610 may be applied to each word-line contact 630. The detection signal may be applied using a charged-particle beam having a small beam current to form a small probe spot. The small probe spot may allow high-resolution imaging, among other things. Because the detection signal comprises a small beam current signal, it may not influence the charging state of a word-line or the response signal of a word-line contact exposed to the pre-scan signal. In some embodiments, a multi-beam apparatus may be used to perform voltage contrast inspection of defects. In such cases, the detection signal may be applied using multiple charged-particle beams having small beam currents.

As illustrated in FIG. 6, pixel 660 represents an image of a contact to a non-defective word-line 620 and pixels 670 represent images of contacts to word-lines 640 and 644 associated with a defect 650. In some embodiments, defect 650 may comprise a charge leakage path formed by, for example, an electrically conducting material, between word-line 640 and word-line 644. Defect 650 may cause word-line 640 and word-line 644 to be electrically connected with each other, forming a word-line-word-line leakage defect. In some embodiments, pixels 660 and 670 may represent SEM images acquired based on, but not limited to, secondary electrons or backscattered electrons. As previously discussed with reference to FIG. 5, the under-dosed pre-scan may enable indication of a defect based on voltage contrast between pixels representing a non-defective word-line contact and a defective contact or a pair of defective contacts. An under-dosed pre-scanning of a ROI of a sample may have numerous advantages over the existing voltage contrast inspection techniques using a saturation dosage for flooding the sample in pre-scan mode. An under-dosed pre-scan approach may have some or all of the advantages discussed herein, among others.
i. High inspection throughput—The low dosage of charged particles during the flooding mode may result in a significant gain of throughput at least because a larger field-of-view (FOV) and lower average voltage signal may be applied during pre-scan. Additionally, primary beam flooding (PBF) and high-voltage (HV) flooding may be applicable, which may be more efficient to charge up a WL in comparison to conventional inspection techniques.
ii. Larger ROI—The region of interest may be expanded to pre-scan larger areas, such as the entire staircase structure of a 3D NAND device.

iii. Flexibility in stage accuracy requirement-Because the ROI may be expanded to cover larger areas and more features with a large field-of-view (FOV), the accuracy requirements in positioning the stage may be less stringent.
iv. Compatibility and Scalability—The proposed under-dosed pre-scan may be compatible with single charged-particle beam as well as multi-beam apparatuses. The approach may be used across a wide variety of inspection tools without additional hardware, design modifications, or controller modifications.

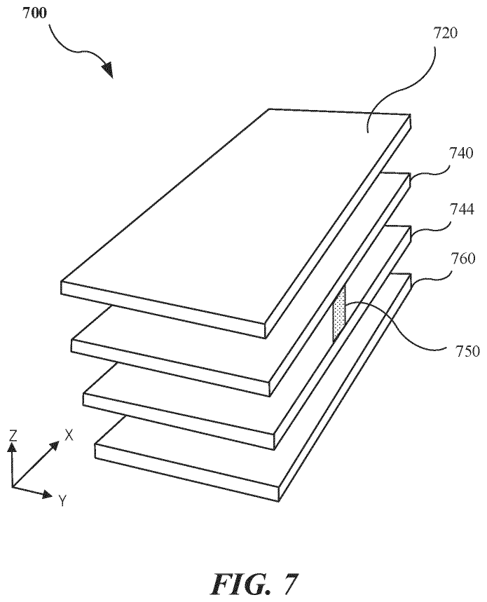

FIG. 7 illustrates a perspective view of an exemplary stack 700 of word-lines, consistent with some embodiments of the disclosure. Although only four word-lines or word-plates (WPs) are shown, it is appreciated that any number of word-lines may be present in a word-line stack of a 3D NAND device, as appropriate. In some embodiments, a word-line may comprise a capacitor or a parallel plate capacitor. As an example, word-line 740 may be a rectangular three-dimensional plate having a length, a width, and a thickness along x, y, and z axes, respectively. The orientation of the axes is represented in FIG. 7 for illustrative purposes. In some embodiments, the aspect ratio of a word-line may be 4000:60:1. It is appreciated that the aspect ratio may be higher or lower as well. Aspect ratio of a word-line, as used herein, refers to the ratio between the length, width, and thickness of the word-line. In some embodiments, word-line 720 may have a length of several millimeters (mm), a width of several micrometers (μm), and a thickness of several nanometers (nm). For example, word-line 720 may be 2 mm long, 10 μm wide, and 100 nm thick. Defect 750 may electrically connect WLs 740 and 744 rendering the pair of word-lines as defective word-lines. Defect 750 may provide a path for leakage of charges between word-line 740 and word-line 744, forming a word-line-to-word-line leakage defect.

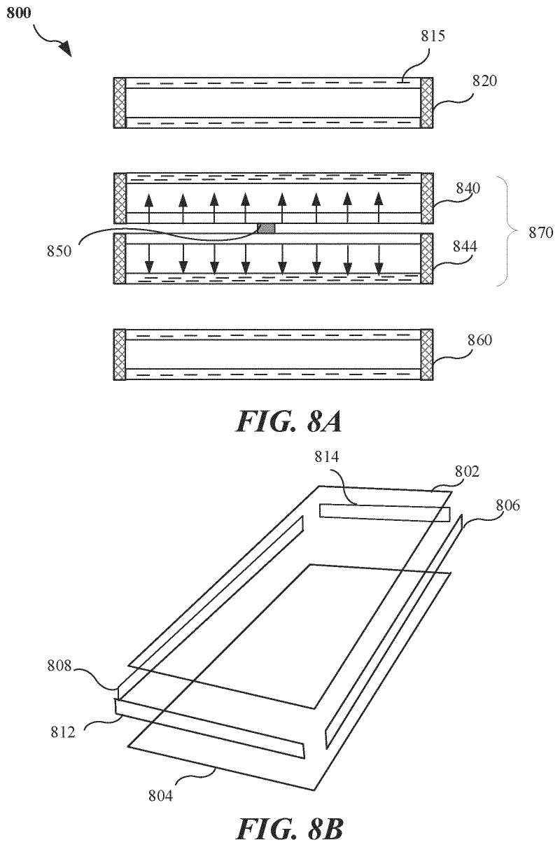

Reference is now made to FIG. 8A, which illustrates a cross-section view 800 of an exemplary word-line stack including a defect, consistent with embodiments of the present disclosure. Word-line stack 800 may be analogous to word-line stack 700 of FIG. 7. A word-line such as word-line 820 may comprise a plurality of surfaces including a top surface 802, a bottom surface 804, a front surface 806, a rear surface 808, and side surfaces 812 and 814, as illustrated in FIG. 8B, which is an exploded view of a word-line. In some embodiments, WL 820 may provide multiple surfaces for charge accumulation. However, the charge distribution across the different surfaces may be based on dimensions of the surface. A majority of charges may be distributed on top and bottom surfaces (e.g., top surface 802 and bottom surface 804 of FIG. 8B), while the remaining charges may be distributed across the front, the rear, and the side surfaces. As an example, more than 90% of the applied charges may be distributed on top surface 802 and bottom surface 804, and less than 10% of the applied charges may be distributed on the remaining surfaces. In such a configuration, the capacitance of word-line 820 may depend mainly on the area of the top surface 802 and bottom surface 804 and weakly on remaining front, rear, and side surfaces 806, 808, 812, and 814, respectively.

Turning back to FIG. 8A, word-lines 820 and 860 represent non-defective word-lines and word-lines 840 and 844 represent defective word-lines, electrically connected with each other through defect 850. In some embodiments, applying a voltage signal to non-defective word-line 820 may cause a majority of charges 815 to accumulate on top and bottom surfaces separated by a distance equal to the thickness of word-line 820. In the presence of defect 850, which forms a word-line-word-line leakage path, word-lines 840 and 844 may function as a single capacitor 870. In such a case, the bottom surface of word-line 840 and the top surface of word-line 844, which are electrically connected with each other through defect 850, may not store any charges. Single capacitor 870 may have twice the thickness of a non-defective word-line (e.g., word-line 820) but substantially similar top and bottom surface areas, thereby resulting in a small increase in total capacitance. In other words, if a pair of word-lines is electrically shorted to form a single capacitor such as capacitor 870, the total capacitance of the defective word-line pair may increase by a small amount, but it may receive charges from two separate contacts, corresponding to word-lines 840 and 844, thereby charging up the single capacitor 870 faster than non-defective word-lines and saturating earlier, as illustrated by plot 520 of FIG. 5. This effect may allow the application of a lower dosage to each contact or contact pad, for example 0.55× of saturation dosage, and saturate the defective word-lines while the non-defective word-lines are still unsaturated. The difference in gray level value signals at 0.55× of saturation dosage may be used to determine whether there is a defect causing a leakage between two word-lines, for example.

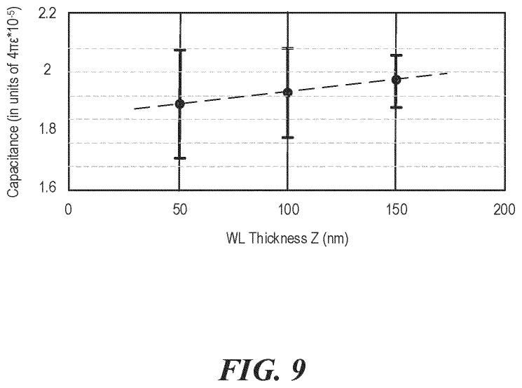

In some embodiments, the total capacitance of single capacitor 870 may be simulated using a Monte-Carlo simulation model based on the Random Walk-on Boundary method, for example. It is appreciated that other simulation models and methods may be used to simulate the numerical value of capacitance for a capacitor with known dimensions. The model may further allow approximation of dimensions to numerically and theoretically predict the capacitance of a capacitor. FIG. 9 illustrates a data plot of simulated capacitance values for a range of capacitor thicknesses, consistent with some embodiments of the present disclosure.

As illustrated in FIG. 9 and as previously discussed, increasing the thickness of a capacitor increases the capacitance by a smaller amount, in comparison with the increase in capacitance by increasing the top and the bottom surface area. The data plot shown in FIG. 9 represents simulated or predicted values of capacitance (in units of 4πε*10⁻⁵ Farads) for a WL 200 μm long, 3 μm wide, and thicknesses ranging from 50 nm to 150 nm. The slope of the line connecting the data points for capacitance values of different thicknesses of a capacitor indicates the dependence relationship. In some cases, a 2× increase in thickness may increase the capacitance by 15% or less, 12% or less, 10% or less, 8% or less, 6% or less, or 5% or less.

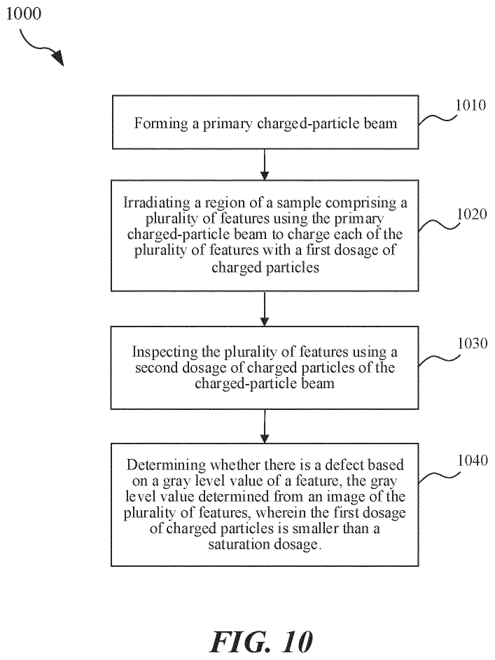

Reference is now made to FIG. 10, which illustrates a process flowchart representing an exemplary method 1000 of detecting a defect using a charged-particle beam apparatus, consistent with embodiments of the present disclosure. One or more steps of method 1000 may be performed by controller 50 of EBI system 100, as shown in FIG. 2, for example. For example, controller 50 may instruct a module of a charged-particle beam apparatus to activate a charged-particle source to generate primary charged particle beam (e.g., electron beam), applying a signal to charge a plurality of features in a region of interest of a sample (e.g., sample 250 of FIG. 2), and carry out other functions.

In step 1010, a charged-particle source is activated to emit charged particles. The charged particles may form a charged-particle beam (e.g., primary charged-particle beam 204 of FIG. 2). The electron source may be activated by a controller (e.g., controller 50 of FIG. 2). For example, the electron source may be controlled to emit primary electrons to form an electron beam along a primary optical axis (e.g., primary optical axis 201 of FIG. 2). The electron source may be activated remotely, for example, by using a software, an application, or a set of instructions for a processor of a controller to power the electron source through a control circuitry. The primary electron beam may pass through a Coulomb aperture array (e.g., Coulomb aperture array 224 of FIG. 2) and a beam-limit aperture array (e.g., beam-limit aperture array 305 of FIG. 3) to adjust the beam size or beam current of the primary electron beam and form a probing beam incident on the sample (e.g., sample 250 of FIG. 2).

In step 1020, a region of interest (ROI) of the sample is irradiated with a first dosage of charged particles from the primary charged-particle beam. The ROI may include a plurality of features, such as contacts or contact pads (e.g., contact pad 340 of FIG. 3) to a plurality of word-lines (e.g., word-line 320 of FIG. 3 or word-lines 720, 740, 744, or 760 of FIG. 7). Step 1020 may comprise a pre-scan mode or a flooding mode of a voltage contrast inspection technique, wherein each feature of interest in the region of interest is flooded with a first dosage of charged particles such as, for example, electrons of a primary electron beam in a SEM tool. The first dosage of charged particles may be smaller than a saturation dosage (e.g., saturation dosage D_{S} of FIG. 4). Irradiating the features of interest may enable identification of defects based on the charges stored, which forms a gray level value contrast signal of the feature in an acquired image, such as a SEM image.

In step 1030, each feature of interest, such as contact pads, to each word-line in the staircase structure (e.g., staircase structure of a 3D NAND device shown in FIG. 3) in the region of interest may be inspected using a second dosage of charged particles of the primary charged-particle beam. The second dosage of charged particles may be substantially smaller than the first dosage such that the second dosage has a negligible influence on the charging state of the features of interest caused by the exposure to first dosage of charged particles.

In some embodiments, a charged particle detector may be used to detect signal charged particles generated from the region of interest of the sample upon interaction with the charged particles of the primary charged-particle beam. An image may be formed based on the detected signal charged particles. The image formed may comprise a SEM image, or other suitable image in gray scale.

In step 1040, a defect may be detected based on the gray level values of the features in the acquired image. The features (e.g., contact pads 340 of FIG. 3) exposed to the first dosage and inspected by the second dosage of charged particles may form a pixel having a gray level value based on the presence of a defect in the corresponding word-lines. For example, if a pair of word-lines are electrically connected with each other through a defect (e.g., defect 650 of FIG. 6 or defect 750 of FIG. 7), the corresponding contact pads may appear in the acquired image as bright pixels having high gray level value signals. For a non-defective word-line, the corresponding contact pad may appear as a darker pixel with a low gray level value signal, thereby enabling detection of defects based on the gray level value signal of the pixels representing contact pads to corresponding word-lines.

Some of the advantages of the under-dosed pre-scan approach include improved inspection throughput, larger regions of interest, less stringent stage accuracy requirement, compatibility with single beam and multi-beam inspection apparatuses, stability in charging control, among other things.

A non-transitory computer readable medium may be provided that stores instructions for a processor of a controller (e.g., controller 50 of FIG. 1) to carry out image inspection, image acquisition, activating charged-particle source, irradiating a region of a sample with a first dosage of charged particles, inspecting a region of a sample with a second dosage of charged particles different from the first dosage, determining whether there is a defect based on a gray level value of a feature from an acquired image of the region of the sample, etc. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments of the present disclosure may further be described using the following clauses:
1. A charged-particle beam apparatus, comprising:
a charged-particle source configured to emit charged particles, the emitted charged particles forming a primary charged-particle beam;
a controller including circuitry configured to:
irradiate a region of a sample comprising a plurality of features with a first dosage of charged particles of the primary charged-particle beam;
inspect the plurality of features using a second dosage of the charged particles of the primary charged-particle beam, the second dosage being different from the first dosage;
acquire an image of the inspected plurality of features; and
determine whether there is a defect based on a gray level value of a feature of the plurality of features, the gray level value determined from the acquired image of the plurality of features,
wherein the first dosage is smaller than a saturation dosage, and wherein the saturation dosage comprises a total number of charged particles exceeding a charge storage capacity of the feature.
2. The apparatus of clause 1, further comprising a charged-particle detector configured to detect a plurality of signal charged particles generated upon interaction of the charged particles with the plurality of features on the sample.
3. The apparatus of clause 2, wherein the controller having circuitry further configured to form the image based on the detected plurality of signal charged particles.
4. The apparatus of any one of clauses 1-3, wherein the feature comprises a contact pad, the contact pad configured to form an electrical connection to a capacitor.
5. The apparatus of clause 4, wherein the capacitor comprises a word-line of a memory device.
6. The apparatus of clause 5, wherein the defect comprises an electrical short or a current leakage path between at least two word-lines.
7. The apparatus of any one of clauses 1-6, wherein the controller having circuitry further configured to identify at least one feature associated with the defect based on the gray level of the at least one feature.
8. The apparatus of any one of clauses 1-7, wherein a gray level value of a defective feature irradiated with the first dosage of charged particles is higher than a gray level value of a non-defective feature irradiated with the first dosage of charged particles.
9. The apparatus of any one of clauses 1-8, wherein the second dosage of charged particles is smaller than the first dosage.
10. The apparatus of any one of clauses 1-9, wherein the second dosage of charged particles is smaller than the saturation dosage.
11. The apparatus of any one of clauses 1-10, wherein the first dosage is smaller than a threshold dosage, the threshold dosage comprising a total number of charged particles substantially similar to the charge storage capacity of the feature.
12. The apparatus of clause 11, wherein the threshold dosage is smaller than the saturation dosage.
13. The apparatus of any one of clauses 1-12, wherein a ratio of the first dosage of charged particles to the saturation dosage is between 0.4 and 0.8.
14. The apparatus of clause 13, wherein the ratio is between 0.5 and 0.7.
15. The apparatus of clause 13, wherein the ratio is between 0.55 and 0.65.
16. The apparatus of clause 13, wherein the ratio is 0.55.
17. A charged-particle beam apparatus, comprising:
a charged-particle source configured to emit charged particles, the emitted charged particles forming a primary charged-particle beam;
a controller including circuitry configured to:
irradiate a region of a sample comprising a plurality of contact pads with a first dosage of charged particles of the primary charged-particle beam, the plurality of contact pads configured to form an electrical connection to a corresponding plurality of word-lines of a memory device;
inspect the plurality of contact pads using a second dosage of the charged particles of the primary charged-particle beam, the second dosage being different from the first dosage;
acquire an image of the inspected plurality of contact pads; and
determine whether there is a defect based on a gray level value of a contact pad of the plurality of contact pads, the gray level value determined from the acquired image of the plurality of contact pads,
wherein the first dosage is smaller than a saturation dosage, and wherein the saturation dosage comprises a total number of charged particles exceeding a charge storage capacity of a word-line of the plurality of word-lines.
18. The apparatus of clause 17, further comprising a charged-particle detector configured to detect a plurality of signal charged particles generated upon interaction of the charged particles with the plurality of contact pads on the sample.
19. The apparatus of clause 18, wherein the controller having circuitry further configured to form the image based on the detected plurality of signal charged particles.
20. The apparatus of any one of clauses 17-19, wherein the plurality of word-lines comprises a plurality of capacitors.
21. The apparatus of any one of clauses 17-20, wherein the defect comprises an electrical short or a current leakage path between at least two word-lines of the plurality of word-lines.
22. The apparatus of any one of clauses 17-21, wherein the controller having circuitry further configured to identify at least one contact pad associated with the defect based on the gray level of the at least one contact pad.
23. The apparatus of any one of clauses 17-22, wherein a gray level value of a contact pad corresponding to a defective word-line irradiated with the first dosage of charged particles is higher than a gray level value of a contact pad corresponding to a non-defective contact pad irradiated with the first dosage of charged particles.
24. The apparatus of any one of clauses 17-23, wherein the second dosage of charged particles is smaller than the first dosage.
25. The apparatus of any one of clauses 17-24, wherein the second dosage of charged particles is smaller than the saturation dosage.
26. The apparatus of any one of clauses 17-25, wherein the first dosage is smaller than a threshold dosage, the threshold dosage comprising a total number of charged particles substantially similar to the charge storage capacity of a word-line of the plurality of word-lines.
27. The apparatus of clause 26, wherein the threshold dosage is smaller than the saturation dosage.
28. The apparatus of any one of clauses 17-27, wherein a ratio of the first dosage of charged particles to the saturation dosage is between 0.4 and 0.8.
29. The apparatus of clause 28, wherein the ratio is between 0.5 and 0.7.
30. The apparatus of clause 28, wherein the ratio is between 0.55 and 0.65.
31. The apparatus of clause 28, wherein the ratio is 0.55.
32. A method for detecting a defect using a charged-particle beam apparatus, the method comprising:
irradiating a region of a sample comprising a plurality of features using a charged-particle beam to charge each of the plurality of features with a first dosage of charged particles of the charged-particle beam;
inspecting the plurality of features using a second dosage of charged particles of the charged-particle beam, the second dosage being different from the first dosage;
acquiring an image of the inspected plurality of features; and
determining whether there is a defect based on a gray level value of a feature, the gray level value determined from the acquired image of the plurality of features,
wherein the first dosage is smaller than a saturation dosage, and wherein the saturation dosage comprises a total number of charged particles exceeding a charge storage capacity of the feature.
33. The method of clause 32, further comprising detecting, using a charged-particle detector, a plurality of signal charged particles generated upon interaction of the charged particles with the plurality of features on the sample.
34. The method of clause 33, further comprising forming the image based on the detected plurality of signal charged particles.
35. The method of any one of clauses 32-34, wherein the feature comprises a contact pad, the contact pad configured to form an electrical connection to a capacitor.
36. The method of clause 35, wherein the capacitor comprises a word-line of a memory device.
37. The method of clause 36, wherein the defect comprises an electrical short or a current leakage path between at least two word-lines.
38. The method of any one of clauses 32-37, further comprising identifying at least one feature associated with the defect based on the gray level of the at least one feature.
39. The method of any one of clauses 32-38, wherein a gray level value of a defective feature irradiated with the first dosage of charged particles is higher than a gray level value of a non-defective feature irradiated with the first dosage of charged particles.
40. The method of any one of clauses 32-39, wherein the second dosage of charged particles is smaller than the first dosage.
41. The method of any one of clauses 32-40, wherein the second dosage of charged particles is smaller than the saturation dosage.
42. The method of any one of clauses 32-41, wherein the first dosage is smaller than a threshold dosage, the threshold dosage comprising a total number of charged particles substantially similar to the charge storage capacity of the feature.
43. The method of clause 42, wherein the threshold dosage is smaller than the saturation dosage.
44. The method of any one of clauses 32-43, wherein a ratio of the first dosage of charged particles to the saturation dosage is between 0.4 and 0.8.
45. The method of clause 44, wherein the ratio is between 0.5 and 0.7.
46. The method of clause 44, wherein the ratio is between 0.55 and 0.65.
47. The method of clause 44, wherein the ratio is 0.55.
48. A method for detecting a defect using a charged-particle beam apparatus, the method comprising: irradiating a region of a sample comprising a plurality of contact pads using a charged-particle beam to charge each of the plurality of contact pads with a first dosage of charged particles of the charged-particle beam, the plurality of contact pads configured to form an electrical connection to a corresponding plurality of word-lines of a memory device;
inspecting the plurality of contact pads using a second dosage of charged particles of the charged-particle beam, the second dosage being different from the first dosage;
acquiring an image of the plurality of contact pads; and
determining whether there is a defect based on a gray level value of a contact pad of the plurality of contact pads, the gray level value determined from the acquired image of the plurality of contact pads, wherein the first dosage is smaller than a saturation dosage, and wherein the saturation dosage comprises a total number of charged particles exceeding a charge storage capacity of a word-line of the plurality of word-lines.
49. The method of clause 48, further comprising detecting, using a charged-particle detector, a plurality of signal charged particles generated upon interaction of the charged particles with the plurality of contact pads on the sample.
50. The method of clause 49, further comprising forming the image based on the detected plurality of signal charged particles.
51. The method of any one of clauses 48-50, wherein the plurality of word-lines comprises a plurality of capacitors.
52. The method of any one of clauses 48-51, wherein the defect comprises an electrical short or a current leakage path between at least two word-lines of the plurality of word-lines.
53. The method of any one of clauses 48-52, further comprising identifying at least one contact pad associated with the defect based on the gray level of the at least one contact pad.
54. The method of any one of clauses 48-53, wherein a gray level value of a contact pad corresponding to a defective word-line irradiated with the first dosage of charged particles is higher than a gray level value of a contact pad corresponding to a non-defective contact pad irradiated with the first dosage of charged particles.
55. The method of any one of clauses 48-54, wherein the second dosage of charged particles is smaller than the first dosage.
56. The method of any one of clauses 48-55, wherein the second dosage of charged particles is smaller than the saturation dosage.
57. The method of any one of clauses 48-56, wherein the first dosage is smaller than a threshold dosage, the threshold dosage comprising a total number of charged particles substantially similar to the charge storage capacity of a word-line of the plurality of word-lines.
58. The method of clause 57, wherein the threshold dosage is smaller than the saturation dosage.
59. The method of any one of clauses 48-58, wherein a ratio of the first dosage of charged particles to the saturation dosage is between 0.4 and 0.8.
60. The method of clause 59, wherein the ratio is between 0.5 and 0.7.
61. The method of clause 59, wherein the ratio is between 0.55 and 0.65.
62. The method of clause 59, wherein the ratio is 0.55.
63. A non-transitory computer readable medium storing a set of instructions that is executable by one or more processors of a charged-particle beam apparatus to cause the charged-particle beam apparatus to perform a method for detecting a defect, the method comprising:
activating a charged-particle source configured to emit charged particles, the emitted charged particles forming a primary charged-particle beam;
irradiating a region of a sample comprising a plurality of features using the primary charged-particle beam to charge each of the plurality of features with a first dosage of charged particles of the primary charged-particle beam;
inspecting the plurality of features using a second dosage of charged particles of the primary charged-particle beam, the second dosage being different from the first dosage;
acquiring an image of the inspected plurality of features; and
determining whether there is a defect based on a gray level value of a feature, the gray level value
determined from the acquired image of the plurality of features,
wherein the first dosage is smaller than a saturation dosage, and wherein the saturation dosage comprises a total number of charged particles exceeding a charge storage capacity of the feature.
64. A non-transitory computer readable medium storing a set of instructions that is executable by one or more processors of a charged-particle beam apparatus to cause the charged-particle beam apparatus to perform a method for detecting a defect, the method comprising:
activating a charged-particle source configured to emit charged particles, the emitted charged particles forming a primary charged-particle beam;
irradiating a region of a sample comprising a plurality of contact pads using the primary charged-particle beam to charge each of the plurality of contact pads with a first dosage of charged particles of the primary charged-particle beam, the plurality of contact pads configured to form an electrical connection to a corresponding plurality of word-lines of a memory device;
inspecting the plurality of contact pads using a second dosage of charged particles of the primary charged-particle beam, the second dosage being different from the first dosage;
acquiring an image of the plurality of contact pads; and
determining whether there is a defect based on a gray level value of a contact pad of the plurality of contact pads, the gray level value determined from the acquired image of the plurality of contact pads, wherein the first dosage is smaller than a saturation dosage, and wherein the saturation dosage comprises a total number of charged particles exceeding a charge storage capacity of a word-line of the plurality of word-lines.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A charged-particle beam apparatus, comprising:
a charged-particle source configured to emit charged particles, the emitted charged particles forming a primary charged-particle beam;
a controller including circuitry configured to:
irradiate a region of a sample comprising a plurality of features with a first dosage of charged particles of the primary charged-particle beam;
inspect the plurality of features using a second dosage of the charged particles of the primary charged-particle beam, the second dosage being different from the first dosage;
acquire an image of the inspected plurality of features; and
determine whether there is a defect based on a gray level value of a feature of the plurality of features, the gray level value determined from the acquired image of the plurality of features,
wherein the first dosage is smaller than a saturation dosage, and wherein the saturation dosage comprises a total number of charged particles exceeding a charge storage capacity of the feature.

2. The apparatus of claim 1, further comprising a charged-particle detector configured to detect a plurality of signal charged particles generated upon interaction of the charged particles with the plurality of features on the sample.

3. The apparatus of claim 2, wherein the controller having circuitry further configured to form the image based on the detected plurality of signal charged particles.

4. The apparatus of claim 1, wherein the feature comprises a contact pad, the contact pad configured to form an electrical connection to a capacitor.

5. The apparatus of claim 4, wherein the capacitor comprises a word-line of a memory device.

6. The apparatus of claim 5, wherein the defect comprises an electrical short or a current leakage path between at least two word-lines.

7. The apparatus of claim 1, wherein the controller having circuitry further configured to identify at least one feature associated with the defect based on the gray level of the at least one feature.

8. The apparatus of claim 1, wherein a gray level value of a defective feature irradiated with the first dosage of charged particles is higher than a gray level value of a non-defective feature irradiated with the first dosage of charged particles.

9. The apparatus of claim 1, wherein the second dosage of charged particles is smaller than the first dosage.

10. The apparatus of claim 1, wherein the second dosage of charged particles is smaller than the saturation dosage.

11. The apparatus of claim 1, wherein the first dosage is smaller than a threshold dosage, the threshold dosage comprising a total number of charged particles substantially similar to the charge storage capacity of the feature.

12. The apparatus of claim 11, wherein the threshold dosage is smaller than the saturation dosage.

13. The apparatus of claim 1, wherein a ratio of the first dosage of charged particles to the saturation dosage is between 0.4 and 0.8.

14. The apparatus of claim 13, wherein the ratio is between 0.5 and 0.7.

15. The apparatus of claim 13, wherein the ratio is between 0.55 and 0.65.

16. A method for detecting a defect using a charged-particle beam apparatus, the method comprising:
irradiating a region of a sample comprising a plurality of features using a charged-particle beam to charge each of the plurality of features with a first dosage of charged particles of the charged-particle beam;
inspecting the plurality of features using a second dosage of charged particles of the charged-particle beam, the second dosage being different from the first dosage;
acquiring an image of the inspected plurality of features; and
determining whether there is a defect based on a gray level value of a feature, the gray level value determined from the acquired image of the plurality of features,
wherein the first dosage is smaller than a saturation dosage, and wherein the saturation dosage comprises a total number of charged particles exceeding a charge storage capacity of the feature.

17. The method of claim 16, further comprising detecting, using a charged-particle detector, a plurality of signal charged particles generated upon interaction of the charged particles with the plurality of features on the sample.

18. The method of claim 17, further comprising forming the image based on the detected plurality of signal charged particles.

19. The method of claim 16, wherein the feature comprises a contact pad, the contact pad configured to form an electrical connection to a capacitor.

20. A non-transitory computer readable medium storing a set of instructions that is executable by one or more processors of a charged-particle beam apparatus to cause the charged-particle beam apparatus to perform operations for detecting a defect, the operations comprising:
activating a charged-particle source configured to emit charged particles, the emitted charged particles forming a primary charged-particle beam;
irradiating a region of a sample comprising a plurality of features using the primary charged-particle beam to charge each of the plurality of features with a first dosage of charged particles of the primary charged-particle beam;
inspecting the plurality of features using a second dosage of charged particles of the primary charged-particle beam, the second dosage being different from the first dosage;
acquiring an image of the inspected plurality of features; and
determining whether there is a defect based on a gray level value of a feature, the gray level value determined from the acquired image of the plurality of features,
wherein the first dosage is smaller than a saturation dosage, and wherein the saturation dosage comprises a total number of charged particles exceeding a charge storage capacity of the feature.
